(19) United States
(12) Patent Application Publication
(10) Pub. No.: US 2014/0091398 A1
(43) Pub. Date: Apr. 3, 2014

(54) SEMICONDUCTOR DEVICE, SEMICONDUCTOR WAFER, METHOD FOR PRODUCING SEMICONDUCTOR WAFER, AND METHOD FOR PRODUCING SEMICONDUCTOR DEVICE

(71) Applicants: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); THE UNIVERSITY OF TOKYO, Tokyo (JP)

(72) Inventors: Masahiko HATA, Tsukuba-shi (JP); Hisashi YAMADA, Tsukuba-shi (JP); Masafumi YOKOYAMA, Bunkyo-ku (JP); SangHyeon Kim, Bunkyo-ku (JP); Rui ZHANG, Bunkyo-ku (JP); Mitsuru TAKENAKA, Bunkyo-ku (JP); Shinichi TAKAGI, Bunkyo-ku (JP); Tetsuji YASUDA, Tsukuba-shi (JP)

(73) Assignees: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); THE UNIVERSITY OF TOKYO, Tokyo (JP)

(21) Appl. No.: 14/099,204

(22) Filed: Dec. 6, 2013

Related U.S. Application Data
(63) Continuation-in-part of application No. PCT/JP2012/003784, filed on Jun. 11, 2012.

(30) Foreign Application Priority Data
Jun. 10, 2011 (JP) 2011-130731

(51) Int. Cl. H01L 27/092; H01L 21/8238; H01L 21/02

(52) U.S. Cl. CPC H01L 27/092; H01L 21/0254; H01L 21/823807; H01L 21/02381
USPC 257/369; 438/478; 438/199

(57) ABSTRACT

Provided is a semiconductor device including a first source and a first drain of a P-channel-type MISFET formed on a Ge wafer, which are made of a compound having a Ge atom and a nickel atom, a compound having a Ge atom and a cobalt atom, or a compound having a Ge atom, a nickel atom, and a cobalt atom, and a second source and a second drain of an N-channel-type MISFET formed on the Group III-V compound semiconductor, which are made of a compound having a Group III atom, a Group V atom, and a nickel atom, a compound having a Group III atom, a Group V atom, and a cobalt atom, or a compound having a Group III atom, a Group V atom, a nickel atom, and a cobalt atom.

The contents of the following patent applications are incorporated herein by reference:

No. 2011-130731 filed in Japan on Jun. 10, 2011, and

PCT/JP2012/003784 filed on Jun. 11, 2012.

### TECHNICAL FIELD

The present invention relates to a semiconductor device, a semiconductor wafer, a method for producing a semiconductor wafer, and a method for producing a semiconductor device. Note that the present application is based on the research “Technical Development on New Material for Nanoelectronics Semiconductor and New-Structure Nanoelectronic Device—Research and Development on Group III-V Semiconductor Channel Transistor Technology on Silicon Platform” of the year 2010 entrusted by the New Energy and Industrial Technology Development Organization (NEDO) and applies to Art. 19 of Industrial Technology Enhancement Act.

### BACKGROUND ART

Group III-V compound semiconductors such as GaAs and InGaAs have a high electron mobility, whereas Group IV semiconductors such as Ge and SiGe have a high hole mobility. Therefore, a high-performance CMOSFET (Complementary Metal-Oxide-Semiconductor Field-Effect Transistor) can be realized by using a Group III-V compound semiconductor to make an N-channel-type MOSFET (Metal-Oxide-Semiconductor Field-Effect Transistor) and using a Group IV semiconductor to make a P-channel-type MOSFET. Non-patent Document No. 1 discloses a CMOSFET structure in which an N-channel-type MOSFET whose channel is made of a Group III-V compound semiconductor and a P-channel-type MOSFET whose channel is made of Ge are formed on a single wafer.
Non-patent Document No. 1: S. Takagi, et al., SSE, vol. 51, p. 526-536, 2007

### SUMMARY OF THE INVENTION

### Problems to be Solved by the Invention

So as to form, on a single wafer, an N-channel-type MISFET (Metal-Insulator-Semiconductor Field-Effect Transistor) (hereinafter simply referred to as “nMISFET”) whose channel is made of a Group III-V compound semiconductor and a P-channel-type MISFET (hereinafter simply referred to as “pMISFET”) whose channel is made of a Group IV semiconductor, there is required a technique to form, on the same wafer, the Group III-V compound semiconductor to be used for the nMISFET and the Group IV semiconductor to be used for the pMISFET.

So as to inexpensively and efficiently produce an LSI a CMISFET (Complementary Metal-Insulator-Semiconductor Field-Effect Transistor) made up of an nMISFET and a pMISFET, it is preferable to adopt the production process enabling simultaneous formation of an nMISFET and a pMISFET. Simultaneously forming, in particular, the source/drain of the nMISFET and the source/drain of the pMISFET can simplify the process and easily cope with the need for cost reduction and miniaturization of devices.

The source/drain of the nMISFET and the source/drain of the pMISFET can be simultaneously formed by, for example, forming thin films using materials to become a source and a drain on both of the source/drain formation regions of the nMISFET and the source/drain formation regions of the pMISFET, and then patterning the films by photolithography or the like. The Group III-V compound semiconductor crystal layer from which the nMISFET is formed is, however, different from the Group IV semiconductor crystal layer from which the pMISFET is formed, in constituent material. This increases a resistance of the source/drain regions of one or both of the nMISFET and the pMISFET, or increases a contact resistance of the source/drain regions of one or both of the nMISFET and the pMISFET with respect to the source/drain electrodes. It is therefore difficult to reduce a resistance of the source/drain regions of both of the nMISFET and the pMISFET, or a contact resistance of the regions with respect to the source/drain electrodes.

Therefore, it is an object of an aspect of the present invention herein to provide a semiconductor device, and a method for producing a semiconductor device, which can realize simultaneous formation of each source and each drain of an nMISFET and a pMISFET with a smaller resistance in the source/drain regions or a smaller contact resistance of the regions with the source/drain electrodes, when forming, on a single wafer, a CMISFET made up of an nMISFET whose channel is made of a Group III-V compound semiconductor and a pMISFET whose channel is made of a Group IV semiconductor.

### Means for Solving the Problems

In view of the above discussions, according to the first aspect related to the present invention, there is provided a semiconductor device including: a base wafer made of a Ge crystal; a semiconductor crystal layer that is positioned above a partial region of the base wafer and made of a Group III-V compound semiconductor; a P-channel-type MISFET having a channel formed in a part of an area of the base wafer above which the semiconductor crystal layer does not exist and having a first source and a first drain; and an N-channel-type MISFET having a channel formed in a part of the semiconductor crystal layer and having a second source and a second drain, where the first source and the first drain are made of a compound having a Ge atom and a nickel atom, a compound having a Ge atom and a cobalt atom, or a compound having a Ge atom, a nickel atom, and a cobalt atom, and the second source and the second drain are made of a compound having a Group III atom, a Group V atom, and a nickel atom, a compound having a Group III atom, a Group V atom, and a cobalt atom, or a compound having a Group III atom, a Group V atom, a nickel atom, and a cobalt atom.

The aforementioned semiconductor device may include a separation layer that is positioned between the base wafer and the semiconductor crystal layer, and electrically separates the base wafer from the semiconductor crystal layer. When the base wafer is in contact with the separation layer, an area of the base wafer that is in contact with the separation layer may be conductive, and a voltage applied to the area of the base wafer that is in contact with the separation layer may function as a back gate voltage with respect to the N-channel-type MISFET. When the base wafer is in contact with the semiconductor crystal layer on a bonding plane, impurity atoms exhibiting a p-type or n-type conductivity type may be contained in an area of the base wafer in the vicinity of the bonding plane, and impurity atoms exhibiting a conductivity type different from the conductivity type of impurity atoms contained in the base wafer may be contained in an area of the semiconductor crystal layer in the vicinity of the bonding plane.

According to the second aspect related to the present invention, there is provided a semiconductor wafer used for the semiconductor device according to the first aspect of the present invention, the semiconductor wafer including: the base wafer and the semiconductor crystal layer, where the semiconductor crystal layer is positioned above a part of a surface of the base wafer.

A separation layer that is positioned between the base wafer and the semiconductor crystal layer, and electrically separates the base wafer from the semiconductor crystal layer may further be included. In this case, the separation layer may be made of an amorphous insulator, or a semiconductor crystal having a wider band gap than a band gap of a semiconductor crystal constituting the semiconductor crystal layer. When the base wafer is in contact with the semiconductor crystal layer on a bonding plane, impurity atoms exhibiting a p-type or n-type conductivity type may be contained in an area of the base wafer in the vicinity of the bonding plane, and impurity atoms exhibiting a conductivity type different from the conductivity type of impurity atoms contained in the base wafer may be contained in an area of the semiconductor crystal layer in the vicinity of the bonding plane. A plurality of the semiconductor crystal layers may be included, and each of the plurality of semiconductor crystal layers may be arranged regularly within a plane parallel to an upper plane of the base wafer.

According to the third aspect related to the present invention, there is provided a method for producing the semiconductor wafer according to the second aspect, the method including: epitaxial growth of forming the semiconductor crystal layer on a semiconductor crystal layer forming wafer by epitaxial growth; and bonding the semiconductor crystal layer to a partial region of the base wafer, or to a region thereabove. There is also provided a method for producing the semiconductor wafer as stated above, the method including: forming, above a partial region of the base wafer, a separation layer made of a semiconductor crystal having a wider band gap than a band gap of a semiconductor crystal constituting the semiconductor crystal layer by epitaxial growth; and forming the semiconductor crystal layer on the separation layer by epitaxial growth. There is further provided a method for producing the semiconductor wafer as stated above, the method including: incorporating impurity atoms exhibiting a p-type or n-type conductivity type into the vicinity of a surface of the base wafer; and forming the semiconductor crystal layer above a part of the surface of the base wafer by epitaxial growth, where in the forming of the semiconductor crystal layer by epitaxial growth, the base wafer is doped with impurity atoms exhibiting a conductivity type different from a conductivity type of impurity atoms contained in the base wafer.

A crystalline sacrificial layer may be formed on a surface of the semiconductor crystal layer forming wafer by epitaxial growth; where the semiconductor crystal layer forming wafer is separated from the semiconductor crystal layer having been formed by epitaxial growth on the semiconductor crystal layer forming wafer, by removing the crystalline sacrificial layer. It is also possible to include: any one of patterning the semiconductor crystal layers in a regular arrangement after having formed the semiconductor crystal layers by epitaxial growth, or forming the semiconductor crystal layers in a regular arrangement by selective epitaxial growth.

According to the fourth aspect related to the present invention, there is provided a method for producing a semiconductor device including: producing a semiconductor wafer including the semiconductor crystal layer by using the method according to the third aspect for producing the semiconductor wafer; forming a gate electrode via a gate insulating layer, on an area of the base wafer above which the semiconductor crystal layer does not exist, and on the semiconductor crystal layer; forming a metal film selected from the group consisting of a nickel film, a cobalt film, and a nickel/cobalt alloy film, on a source electrode forming region of the base wafer, on a drain electrode forming region of the base wafer, on a source electrode forming region of the semiconductor crystal layer, and on a drain electrode forming region of the semiconductor crystal layer; heating the metal film, thereby forming, in the base wafer, a first source and a first drain made of a compound having a Ge atom and a nickel atom, a compound having a Ge atom and a cobalt atom, or a compound having a Ge atom, a nickel atom, and a cobalt atom, and forming, in the semiconductor crystal layer, a second source and a second drain made of a compound having a Group III atom, a Group V atom, and a nickel atom, a compound having a Group III atom, a Group V atom, and a cobalt atom, or a compound having a Group III atom, a Group V atom, a nickel atom, and a cobalt atom; and removing a non-reacted portion of the metal film.

### BRIEF DESCRIPTION OF THE DRAWINGS

FIG. 1 shows a cross section of a semiconductor device 100.

FIG. 2 shows a cross section of the semiconductor device 100 in a production process.

FIG. 3 shows a cross section of the semiconductor device 100 in a production process.

FIG. 4 shows a cross section of the semiconductor device 100 in a production process.

FIG. 5 shows a cross section of the semiconductor device 100 in a production process.

FIG. 6 shows a cross section of the semiconductor device 100 in a production process.

FIG. 7 shows a cross section of a different semiconductor device in a production process.

FIG. 8 shows a cross section of a different semiconductor device in a production process.

FIG. 9 shows a cross section of a semiconductor device 200.

FIG. 10 is a TEM photograph showing a cross section of a Ta gate portion on the InGaAs layer.

FIG. 11 is a TEM photograph showing a cross section of the Ta gate portion.

FIG. 12 is a SEM photograph of a pMOSFET provided on a Ge wafer and an nMOSFET provided on an InGaAs layer observed from above.

FIG. 13 shows a characteristic relation between the drain current and the drain voltage between the pMOSFET provided on the Ge wafer and the nMOSFET provided on the InGaAs layer.

FIG. 14 shows a characteristic relation between the gate voltage and the drain current for the pMOSFET provided on the Ge wafer.

FIG. 15 shows a characteristic relation between the gate voltage and the drain current for the nMOSFET provided on the InGaAs layer.

FIG. 16 shows a relation of the hole mobility of the pMOSFET provided on the Ge wafer in relation to the charge density Ns.

FIG. 17 shows a relation of the electron mobility of the nMOSFET provided on the InGaAs layer in relation to the charge density Ns.

### MODE FOR CARRYING OUT THE INVENTION

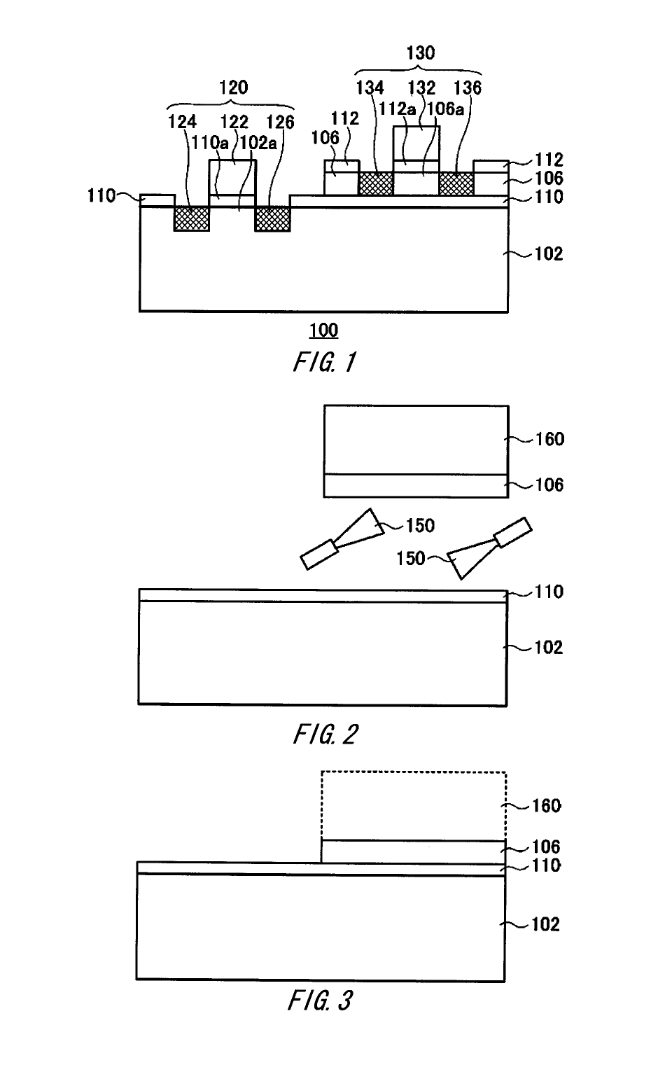

FIG. 1 shows a cross section of a semiconductor device 100. The semiconductor device 100 includes a base wafer 102 made of a Ge crystal and a semiconductor crystal layer 106 made of a Group III-V compound semiconductor, and also includes a separation layer 110 provided between the base wafer 102 and the semiconductor crystal layer 106. The semiconductor device 100 according to this example includes an insulating layer 112 provided on the semiconductor crystal layer 106. Note that from the embodiment example illustrated in FIG. 1, at least two inventions can be interpreted; one invention directed to a semiconductor wafer including, as constituting elements, a base wafer 102 and a semiconductor crystal layer 106, and another invention directed to a semiconductor wafer including, as constituting elements, a base wafer 102, a separation layer 110, and a semiconductor crystal layer 106. A P-channel-type MISFET 120 is formed on the base wafer 102, and an N-channel-type MISFET 130 is formed on the semiconductor crystal layer 106.

The semiconductor crystal layer 106 is positioned above a part of the surface of the base wafer 102. The thickness of the semiconductor crystal layer 106 is preferably equal to or smaller than 20 nm. By making the semiconductor crystal layer 106 to have a thickness of equal to or smaller than 20 nm, the N-channel-type MISFET 130 will have an extremely thin film body. By making the body of the N-channel-type MISFET 130 to be an extremely thin film, the short channel effect can be restrained, and the leak current of the N-channel-type MISFET 130 can be reduced.

In the semiconductor device 100, a Group III-V compound semiconductor crystal layer is used as an N-channel-type MISFET, and a Ge crystal is used as a P-channel-type MISFET. Examples of the Group III-V compound semiconductor crystal include an InₓGa₁₋ₓAs (0<x<1) crystal, a GaAs crystal, or an InP crystal. Another example of the Group III-V compound semiconductor crystal includes a mixed crystal of a Group III-V compound semiconductor that lattice-matches or pseudo-lattice-matches GaAs or InP. A still different example of the Group III-V compound semiconductor crystal includes a laminate of the mixed crystal mentioned above and an InₓGa₁₋ₓAs (0<x<1) crystal, a GaAs crystal, or an InP crystal. Note that a preferable Group III-V compound semiconductor crystal is an InₓGa₁₋ₓAs (0<x<1) crystal. Because the electronic mobility is high in the Group III-V compound semiconductor crystal, and the hole mobility is high in the Group IV semiconductor crystal, especially in Ge, the performance of CMISFET can be maximized.

The separation layer 110 is positioned between the base wafer 102 and the semiconductor crystal layer 106. The separation layer 110 electrically separates the base wafer 102 from the semiconductor crystal layer 106.

The separation layer 110 may be made of an amorphous insulator. When forming the semiconductor crystal layer 106 and the separation layer 110 by wafer bonding, the separation layer 110 will be an amorphous insulator. Examples of the separation layer 110 made of an amorphous insulator include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The separation layer 110 may be made of a semiconductor crystal having a wider band gap than the band gap of the semiconductor crystal constituting the semiconductor crystal layer 106. Such semiconductor crystal can be formed by an epitaxial growth method. When the semiconductor crystal layer 106 is an InGaAs crystal layer or a GaAs crystal layer, examples of the semiconductor crystal constituting the separation layer 110 include an AlGaAs crystal, an AlInGaP crystal, an AlGaInAs crystal, or an InP crystal.

A portion 112a of the insulating layer 112 functions as a gate insulating layer of the N-channel-type MISFET 130. Examples of the insulating layer 112 include a layer made of at least one of Al₂O₃, AlN, Ta₂O₅, ZrO₂, HfO₂, La₂O₃, SiOₓ (e.g., SiO₂), SiNₓ (e.g., Si₃N₄) and SiOₓN_{y}, or a laminate of at least two layers selected from among them.

The P-channel-type MISFET 120 includes a first gate 122, a first source 124, and a first drain 126. The first source 124 and the first drain 126 are formed on the base wafer 102. The P-channel-type MISFET 120 is formed on the region of the base wafer 102 above which no semiconductor crystal layer 106 is positioned, and uses as a channel a portion 102a of the base wafer 102 sandwiched between the first source 124 and the first drain 126. A first gate 122 is formed above the portion 102a. The portion 110a (i.e. channel region) of the separation layer 110 sandwiched between the portion 102a of the base wafer 102 and the first gate 122 may function as a gate insulating layer of the P-channel-type MISFET 120.

The first source 124 and the first drain 126 are made of a compound having a Ge atom and a nickel atom, a compound having a Ge atom and a cobalt atom, or a compound having a Ge atom, a nickel atom, and a cobalt atom. The nickel compound of Ge, the cobalt compound of Ge, and the nickel-cobalt compound of Ge are a low-resistance compound having a lower electric resistance.

The N-channel-type MISFET 130 includes a second gate 132, a second source 134, and a second drain 136. The second source 134 and the second drain 136 are formed on the semiconductor crystal layer 106. The N-channel-type MISFET 130 uses as a channel a portion 106a of the semiconductor crystal layer 106 that is sandwiched between the second source 134 and the second drain 136. The second gate 132 is formed above the portion 106a. A portion 112a of the insulating layer 112 is formed in the region sandwiched between the portion 106a (channel region) of the semiconductor crystal layer 106 and the second gate 132. The portion 112a may also function as a gate insulating layer of the N-channel-type MISFET 130.

The second source 134 and the second drain 136 are made of a compound having a Group III atom, a Group V atom, and a nickel atom, a compound having a Group III atom, a Group V atom, and a cobalt atom, or a compound having a Group III atom, a nickel atom, a Group V atom, a nickel atom, and a cobalt atom. The nickel compound of the Group III-V crystal, the cobalt compound of the Group III-V crystal, and the nickel-cobalt compound of the Group III-V crystal are a low-resistance compound having a lower electric resistance.

As stated above, the source/drain of the P-channel-type MISFET 120 (namely, the first source 124 and the first drain 126) and the source/drain of the N-channel-type MISFET 130 (namely, the second source 134 and the second drain 136) are made of a compound of common atom(s) (i.e. nickel atom, cobalt atom, or both of these atoms). This configuration enables production of the portion using a material film having common atoms, which helps simplify the production process. In addition, by using nickel, cobalt, or both of them as common atom(s), the electric resistance for the source region and the drain region can be reduced in any of the source/drain formed in a Group III-V compound semiconductor crystal layer and the source/drain formed in a Ge crystal. Consequently, it becomes possible to simplify the production process and enhance the performance of the FET.

Note that the first source 124 and the first drain 126 may further include acceptor impurity atoms, and the second source 134 and the second drain 136 may further include donor impurity atoms. Examples of the donor impurity atom added to the source/drain of the N-channel-type MISFET 130 (namely the second source 134 and the second drain 136) include Si, S, Se, and Ge. Examples of the acceptor impurity atom added to the source/drain of the P-channel-type MISFET 120 (namely the first source 124 and the first drain 126) include B, Al, Ga, and In.

FIG. 2 through FIG. 6 respectively show a cross section of the semiconductor device 100 in a production process. First, a base wafer 102 and a semiconductor crystal layer forming wafer 160 are prepared, and a semiconductor crystal layer 106 is formed on the semiconductor crystal layer forming wafer 160 by epitaxial growth. Subsequently, a separation layer 110 is formed on the base wafer 102. The separation layer 110 is formed by a thin-film fabrication method such as ALD (Atomic Layer Deposition), thermal oxidation, evaporation, CVD (Chemical Vapor Deposition), and sputtering. As the semiconductor crystal layer forming wafer 160, an InP wafer, or a GaAs wafer can be selected.

MOCVD (Metal Organic Chemical Vapor Deposition) may be used for the epitaxial crystal growth of the semiconductor crystal layer 106. When forming the Group III-V compound semiconductor crystal layer with the MOCVD method, TMIn (trimethylindium) can be used for an In source, TMGa (trimethylgallium) as a Ga source, AsH₃ (arsine) as an As source, and PH₃ (phosphine) as a P source. Hydrogen can be used as a carrier gas. The reaction temperature can be appropriately adjusted in the range of 300° C. to 900° C., preferably in the range of 450° C. to 750° C. When forming the P-channel-type MISFET 120 on the base wafer 102, a Ge epitaxial crystal layer having further favorable crystallinity can be formed on the surface of the Ge wafer which will be the base wafer. When forming the Ge crystal layer with CVD, GeH₄ (germane) can be used as a Ge source. Hydrogen can be used as a carrier gas. The reaction temperature can be appropriately adjusted in the range of 300° C. to 900° C., preferably in the range of 450° C. to 750° C. By appropriately adjusting the amount of source gas supply and the reaction time, the thickness of the epitaxial growth layer can be controlled.

As shown in FIG. 2, the surface of the semiconductor crystal layer 106 and the surface of the separation layer 110 are activated using an argon beam 150. Subsequently, as shown in FIG. 3, the surface of the semiconductor crystal layer 106 is bonded to a part of the surface of the separation layer 110. The bonding process can be employed in the room temperature. Note that the activation may be employed using a beam of a different rare gas or the like, and is not necessary limited to the argon beam 150. Subsequently, the semiconductor crystal layer forming wafer 160 is etched away using an HCl solution or the like. Consequently, the separation layer 110 is formed on the base wafer 102, and the semiconductor crystal layer 106 is formed on a part of the surface of the separation layer 110. Note that, prior to bonding the separation layer 110 to the base wafer 102, sulfur termination may be employed to terminate the surface of the semiconductor crystal layer 106 using sulfur atoms.

While the separation layer 110 is formed only on the base wafer 102, and the surface of the separation layer 110 is bonded to the surface of the semiconductor crystal layer 106 in the examples shown in FIG. 2 and FIG. 3, the separation layer 110 may also be formed on the semiconductor crystal layer 106, and the surface of the separation layer 110 which is provided on the base wafer 102 may be bonded to the surface of the separation layer 110 which is provided on the semiconductor crystal layer 106. In such a case, it is preferable to subject, to a hydrophilic treatment, the surfaces of the separation layers 110 to be bonded. When having employed the hydrophilic treatment, it is preferable to heat and bond the separation layers 110 to each other. It is alternatively possible to form the separation layer 110 only on the semiconductor crystal layer 106, and then bond the surface of the base wafer 102 to the surface of the separation layer 110 which is provided on the semiconductor crystal layer 106.

While the semiconductor crystal layer 106 is bonded to the separation layer 110 that is provided on the base wafer 102 and then separated from the semiconductor crystal layer forming wafer 160 in the examples shown in FIG. 2 and FIG. 3, the semiconductor crystal layer 106 may be separated from the semiconductor crystal layer forming wafer 160, and then bonded to the separation layer 110. In the latter case, it is preferable to retain the semiconductor crystal layer 106 on an adequate transfer wafer during a period after the semiconductor crystal layer 106 is separated from the semiconductor crystal layer forming wafer 160 and until it is bonded to the separation layer 110.

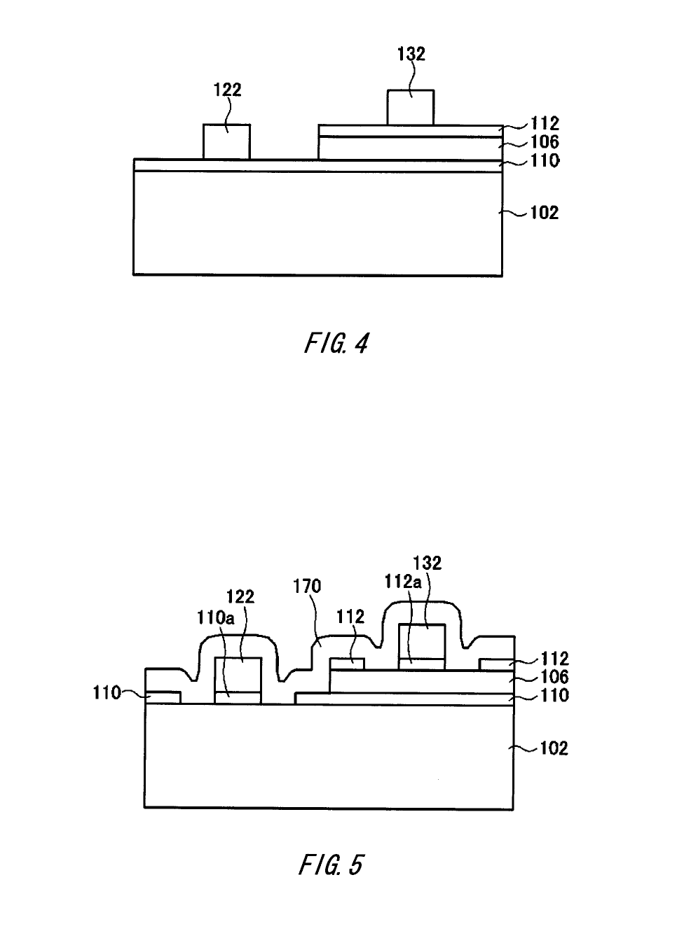

As shown in FIG. 4, an insulating layer 112 is formed on the semiconductor crystal layer 106. The insulating layer 112 is formed by, for example, a thin-film fabrication method such as ALD, thermal oxidation, evaporation, CVD, and sputtering. Further, a thin film of a metal, such as tantalum, which is to be a gate, is formed by evaporation, CVD or sputtering, and the thin film is patterned using photolithography, and a first gate 122 is formed above the base wafer 102 on which no semiconductor crystal layer 106 is formed, and a second gate 132 is formed above the semiconductor crystal layer 106.

As shown in FIG. 5, apertures that reach the base wafer 102 are formed through the separation layer 110 at both sides of the first gate 122, and apertures that reach the semiconductor crystal layer 106 are formed through insulating layer 112 at both sides of the second gate 132. Here, “both sides of each gate” means both sides of each gate in the horizontal direction. Each of the apertures at both sides of the first gate 122 and the apertures at both sides of the second gate 132 corresponds to a region in which one of the first source 124, the first drain 126, the second source 134, and the second drain 136 will be formed. A metal film 170 made of nickel is formed to be in contact with the base wafer 102 and the semiconductor crystal layer 106 exposed on the bottom of these openings respectively. The metal film 170 may be a cobalt film, or a film of a nickel-cobalt alloy.

As shown in FIG. 6, the metal film 170 is heated. By heating, the base wafer 102 reacts with the metal film 170 to form a compound having a Ge atom and an atom constituting the metal film 170, thereby forming the first source 124 and the first drain 126. Simultaneously, the semiconductor crystal layer 106 reacts with the metal film 170 to form a compound having a Group III atom, a Group V atom, and an atom constituting the metal film 170, thereby forming the second source 134 and the second drain 136. When the metal film 170 is a nickel film, a low resistance compound having a Ge atom and a nickel atom is generated as the first source 124 and the first drain 126, and a low resistance compound having a Group III atom and a Group V atom which constitute the second semiconductor crystal layer 106, and a nickel atom is generated as the second source 134 and the second drain 136. When the metal film 170 is a cobalt film, a compound having a Ge atom and a cobalt atom is generated as the first source 124 and the first drain 126, and a compound having a Group III atom, a Group V atom, and a cobalt atom is generated as the second source 134 and the second drain 136. When the metal film 170 is a nickel-cobalt alloy film, a compound having a Ge atom, a nickel atom, and a cobalt atom is generated as the first source 124 and the first drain 126, and a compound having a Group III atom, a Group V atom, a nickel atom, and a cobalt atom is generated as the second source 134 and the second drain 136. A non-reacted portion of the metal film 170 is removed, thereby producing the semiconductor device 100 of FIG. 1.

The heating method for the metal film 170 is preferably RTA (rapid thermal annealing). When the RTA is adopted, the heating temperature can be in the range of 250° C. to 450° C. According to the above-stated method, the first source 124, the first drain 126, the second source 134, and the second drain 136 can be formed by self-aligning them.

According to the above-explained semiconductor device 100 and its production method, the first source 124, the first drain 126, the second source 134, and the second drain 136 can be simultaneously formed by the same process, and so the production process can be simplified. The production cost can be resultantly reduced, and the miniaturization can be employed easily. Moreover, the first source 124, the first drain 126, the second source 134, and the second drain 136 are a low resistance compound having an atom constituting the base wafer 102 or the semiconductor crystal 106 (i.e., a Ge atom or Group III-V atoms) and nickel, cobalt, or a nickel-cobalt alloy. The contact potential barrier between these low resistance compounds, and Ge constituting the channel of the semiconductor device 100 and the semiconductor crystal layer 106 is extremely low, specifically 0.1 eV or below. In addition, the contact of each of the first source 124, the first drain 126, the second source 134, and the second drain 136, with respect to its electrode metal becomes an ohmic contact, and the on-current of the P-channel-type MISFET 120 and the N-channel-type MISFET 130 can be increased. In addition, the resistance for each of the first source 124, the first drain 126, the second source 134, and the second drain 136 will be small, and so it becomes unnecessary to lower the channel resistance of the P-channel-type MISFET 120 and the N-channel-type MISFET 130, and the concentration of the doping impurity atoms can be reduced. Consequently, the mobility of the carrier in the channel layer can be enhanced.

In the semiconductor device 100 explained above, the base wafer 102 is in contact with the separation layer 110, and so, if the region of the base wafer 102 in contact with the separation layer 110 has a conductive property, a voltage can be applied on the region of the base wafer 102 in contact with the separation layer 110, and the mentioned voltage can be used as a back gate voltage for the N-channel-type MISFET 130. These back gate voltages function to increase the on-current for the the N-channel-type MISFET 130, and to decrease the off-current therefor.

In the semiconductor device 100 explained above, there may be a plurality of semiconductor crystal layers 106, and each of the plurality of semiconductor crystal layers 106 may be arranged regularly within a plane parallel to an upper plane of the base wafer 102. By arranging the semiconductor crystal layers 106 regularly, it becomes possible to enhance the productivity of the semiconductor wafer used for the semiconductor device 100. The regular arrangement of the semiconductor crystal layers 106 may be achieved by one of: a method to pattern the semiconductor crystal layers 106 in a regular arrangement after forming the semiconductor crystal layers 106 by epitaxial growth; a method for forming the semiconductor crystal layers 106 in a regular arrangement in advance by selective epitaxial growth; and a method for forming the semiconductor crystal layers 106 on the semiconductor crystal layer forming wafer 160 by epitaxial growth, then separating the semiconductor crystal layers 106 from the semiconductor crystal layer forming wafer 160, then shaping the semiconductor crystal layers 106 into a prescribed shape, and then bonding the semiconductor crystal layers 106 to the base wafer 102 in a regular arrangement. The mentioned arrangement may also be achieved by a combination of a plurality of the methods listed above.

When the separation layer 110 in the aforementioned semiconductor device 100 is made of a semiconductor crystal having a wider band gap than a band gap of a semiconductor crystal constituting the semiconductor crystal layer 106, the separation layer 110 and the semiconductor crystal layer 106 can be sequentially formed on the base wafer 102 by epitaxial growth. When the separation layer 110 is an epitaxially grown crystal, after the separation layer 110 and the semiconductor crystal layer 106 have been formed on the base wafer 102, the separation layer 110 may be oxidized to convert it into an amorphous insulating layer. When the separation layer 110 is, for example, AlAs or AlInP, the separation layer 110 can be subjected to a selective oxidation technology to change the separation layer 110 to an insulating oxide.

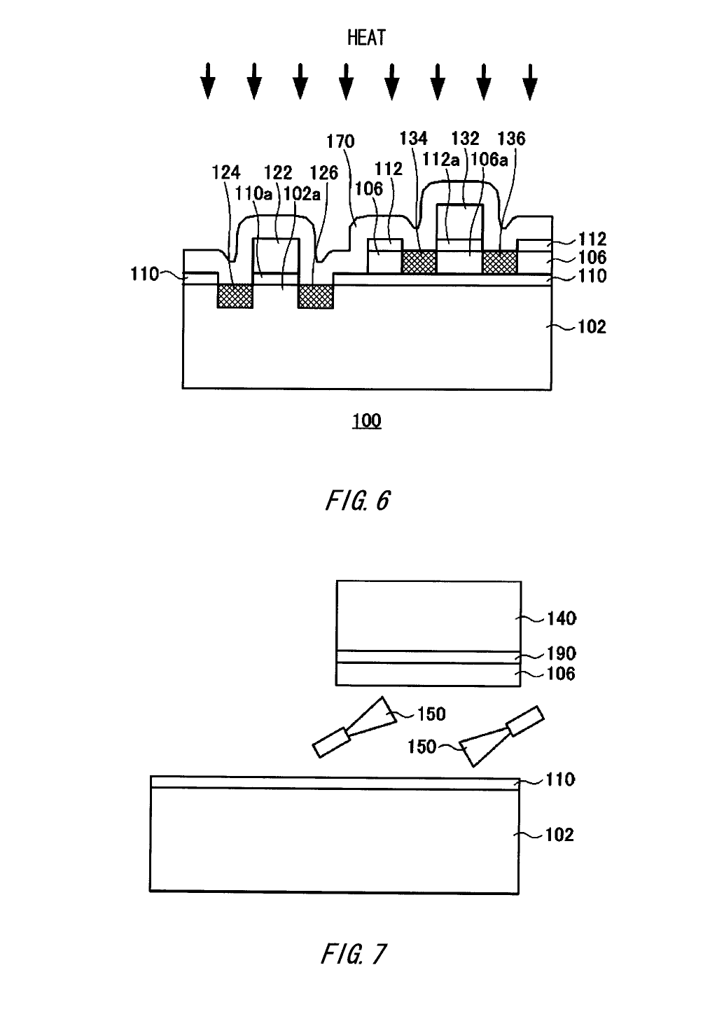

While the semiconductor crystal layer forming wafer is etched away in the bonding process in the production method for the semiconductor device 100 described above, the semiconductor crystal layer forming wafer can be removed by using a crystalline sacrificial layer 190, as shown in FIG. 7. Specifically, prior to forming the semiconductor crystal layer 106 on the semiconductor crystal layer forming wafer 140, a crystalline sacrificial layer 190 is formed by epitaxial growth on the surface of the semiconductor crystal layer forming wafer 140. Thereafter, the semiconductor crystal layer 106 is formed on the surface of the crystalline sacrificial layer 190 by epitaxial growth, the separation layer 110 is formed on the base wafer 102, and an argon beam 150 is used to activate the surface of the semiconductor crystal layer 106 and the surface of the separation layer 110. Subsequently, the surface of the semiconductor crystal layer 106 and the surface of the separation layer 110 are bonded together, and the crystalline sacrificial layer 190 is removed as shown in FIG. 8. The semiconductor crystal layer 106 provided on the semiconductor crystal layer forming wafer 140 is resultantly separated from the semiconductor crystal layer forming wafer 140. According to this method, a semiconductor crystal layer forming wafer can be recycled, to lead to reduction in production cost.

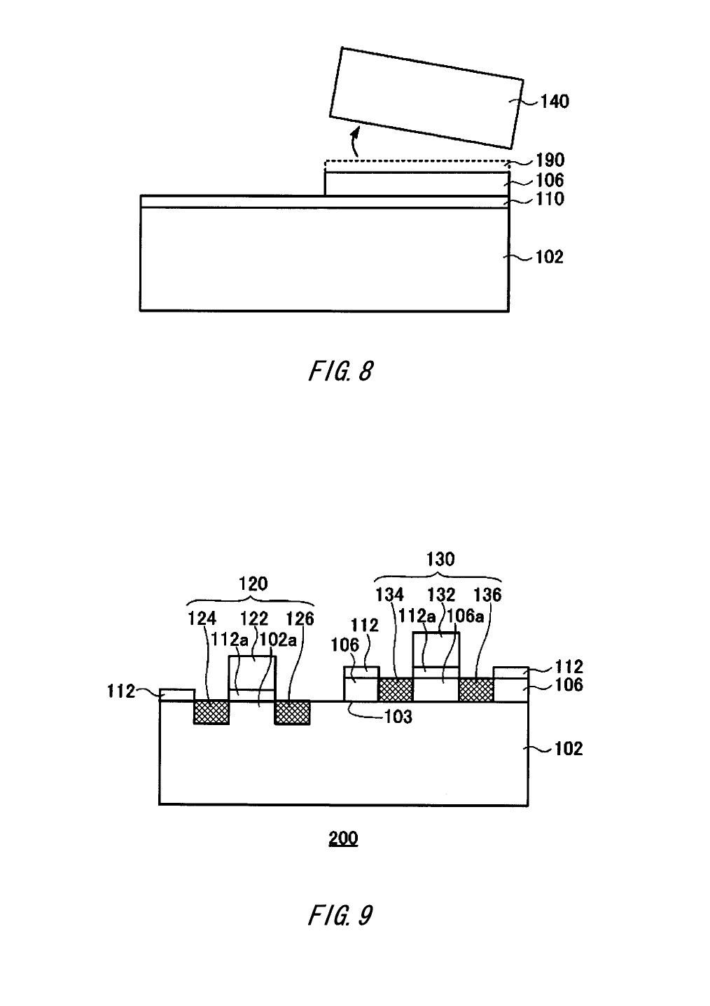

FIG. 9 shows a cross section of a semiconductor device 200. The semiconductor device 200 does not include the separation layer 110 of the semiconductor device 100, and the semiconductor crystal layer 106 is provided to be in contact with the base wafer 102. Because of lacking the separation layer 110, the semiconductor device 200 uses an insulating layer 112 as a gate insulating layer of the P-channel-type MISFET 120. The other configuration of the semiconductor device 200 is the same as that of the semiconductor device 100, and therefore the common elements or the like are not explained in the following.

In the semiconductor device 200, the base wafer 102 is in contact with the semiconductor crystal layer 106 on the bonding plane 103, impurity atoms exhibiting a p-type or n-type conductivity type are contained in an area of the base wafer 102 in the vicinity of the bonding plane 103, and impurity atoms exhibiting a conductivity type different from the conductivity type of impurity atoms are contained in the base wafer 102 in an area of the semiconductor crystal layer 106 in the vicinity of the bonding plane 103. In other words, the semiconductor device 200 includes a pn junction in the vicinity of the bonding plane 103. This indicates that even in a structure without the separation layer 110, the pn junction formed in the vicinity of the bonding plane 103 can allow the base wafer 102 to be electrically separated from the semiconductor crystal layer 106, and to allow the P-channel-type MISFET formed on the base wafer 102 to be electrically separated from the N-channel-type MISFET 130 formed on the semiconductor crystal layer 106.

The semiconductor device 200 can also be produced by replacing the processes after the process of forming the semiconductor crystal layer 106 on the base wafer 102 by epitaxial growth and the insulating layer 112 on the semiconductor crystal layer 106, with the similar processes as in the case of the semiconductor device 100. Note that the pn junction can be formed by doping the semiconductor crystal layer 106 with impurity atoms exhibiting a conductivity type different from the conductivity type of impurity atoms contained in the base wafer 102, in the process of making the base wafer 102 contain impurity atoms exhibiting a p-type or n-type conductivity type in the vicinity of the surface of the base wafer 102, and forming the semiconductor crystal layer 106 by epitaxial growth.

In the structure in which the semiconductor crystal layer 106 is formed directly on the base wafer 102, when the isolation is unnecessary, it is not necessary to form the pn junction as a separation structure. In other words, the semiconductor device 200 may have such a structure that does not include any impurity atoms exhibiting a p-type or n-type conductivity type in an area of the base wafer 102 in the vicinity of the bonding plane 103, and does not include any impurity atoms exhibiting a p-type or n-type conductivity type in an area of the semiconductor crystal layer 106 in the vicinity of the bonding plane 103.

When forming the semiconductor crystal layer 106 directly on the base wafer 102, an annealing treatment can be employed either after or during the epitaxial growth process. By employing the annealing treatment, the dislocation contained in the semiconductor crystal layer 106 will be decreased. The epitaxial growth process may be either a method to grow the semiconductor crystal layer 106 uniformly on the entire surface of the base wafer 102, or a selective growth method that divides the surface of the base wafer 102 minutely using the growth inhibiting layer made of SiO₂, or the like.

### EMBODIMENT EXAMPLE

A Ge (100) wafer was used as the base wafer 102, and an InP (100) wafer was used as the semiconductor crystal layer forming wafer 160. An InGaAs layer was formed by epitaxial growth on the InP (100) wafer, and an Al₂O₃ layer was formed on the InGaAs layer by ALD. An Al₂O₃ layer was formed on the Ge (100) wafer by ALD. The Al₂O₃ layer provided on the InP (100) wafer was bonded to the Al₂O₃ layer provided on the Ge (100) wafer, then annealing was performed, and then the InP (100) wafer was removed by HCl etching. The In ratio of the InGaAs layer was 0.53, and the impurity concentration was in the order of 10¹⁵ atoms/cm³. The impurity concentration of the Ge wafer was 1×10¹⁴ to 2×10¹⁴ atoms/cm³. The resistivity was 7.1 to 9.5 Ω·cm. Three types of devices, whose InGaAs layer has a thickness of 20 nm, 50 nm, and 100 nm respectively, were created.

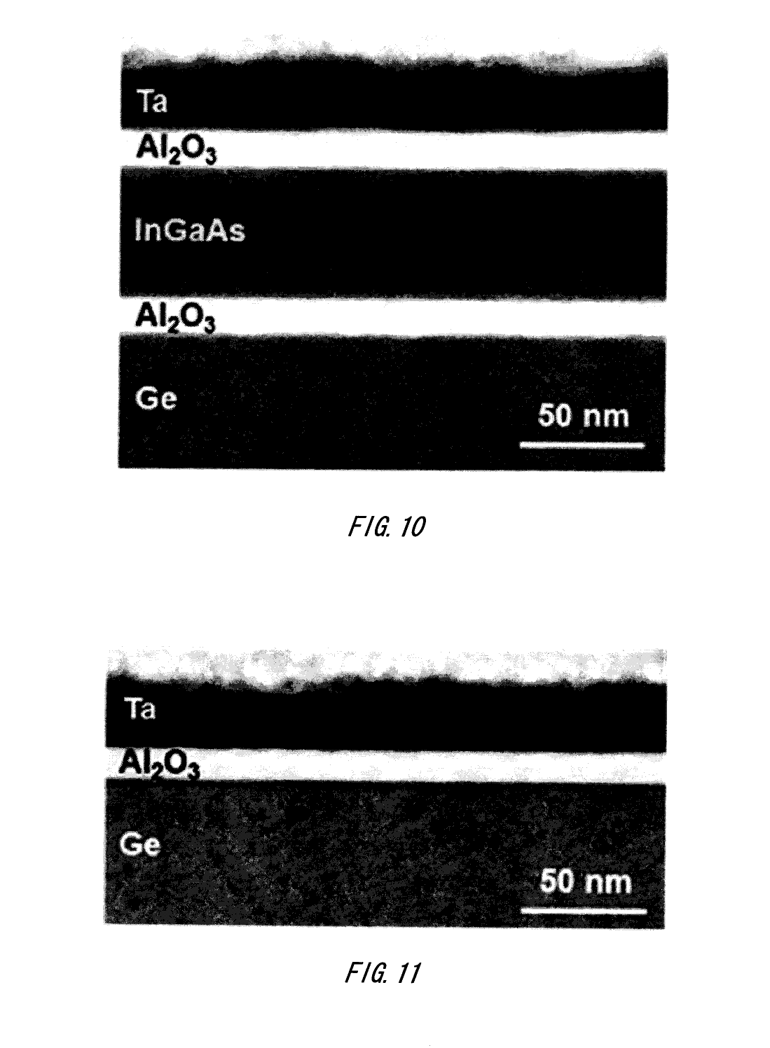

A sulfur compound was used to treat the surface of the InGaAs layer, and then an Al₂O₃ layer was deposited by ALD. A part of the Al₂O₃ layer was etched away, and a part of the InGaAs layer was also etched away, thereby forming a region of the Ge wafer where there was no InGaAs layer. The Ta film was subjected to sputtering, and the Ta film was patterned, thereby forming a gate made of Ta on each of the Al₂O₃ layer provided on the Ge wafer and the Al₂O₃ layer provided on the InGaAs layer. After forming a gate, the resultant was annealed in the temperature of 350° C. FIG. 10 is a TEM photograph showing a cross section of a Ta gate portion provided on the InGaAs layer. FIG. 11 is a TEM photograph showing a cross section of the Ta gate portion provided on the Ge wafer. Both of FIG. 10 and FIG. 11 deal with a case in which the thickness of the InGaAs layer is 50 nm.

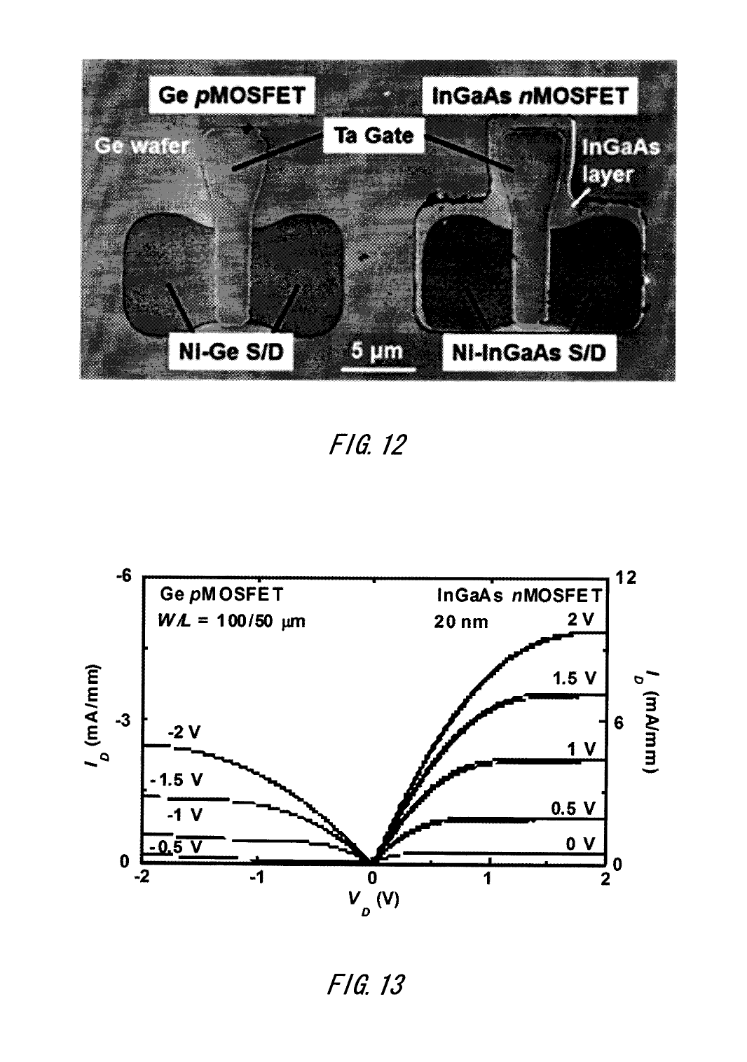

Apertures were formed at both sides of the Al₂O₃ layer, and a Ni film was deposited by sputtering. Ni and Ge as well as Ni and InGaAs were reacted to each other by heating them in the temperature of 250° C. for one minute. The unreacted Ni was removed by wet etching, and each of the InGaAs layer and the Ge wafer was provided with source/drain made of a Ni compound. FIG. 12 is a SEM photograph of a pMOSFET provided on a Ge wafer and an nMOSFET provided on an InGaAs layer observed from above.

FIG. 13 shows a characteristic relation between the drain current and the drain voltage between the pMOSFET provided on the Ge wafer and the nMOSFET provided on the InGaAs layer. The gate width W and the gate length L of each FET were 100 μm and 50 μm, respectively. The thickness of the InGaAs layer was 20 nm. The gate voltage was varied in the range of 0 to −2V (in the case of pMOSFET) and in the range of 0 to 2 V (in the case of nMOSFET). A preferable characteristic relation between the drain current and the drain voltage controlled adequately by the gate voltage was observed.

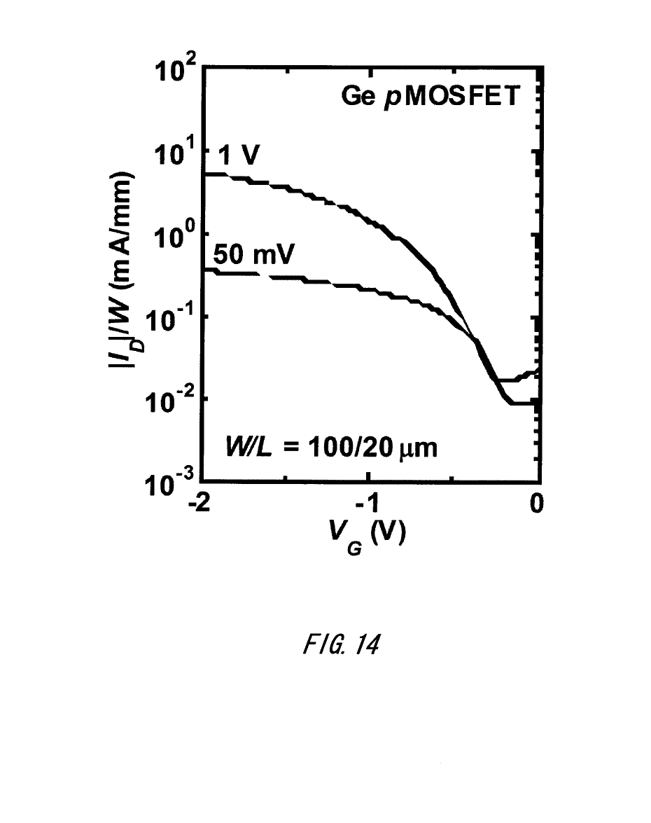

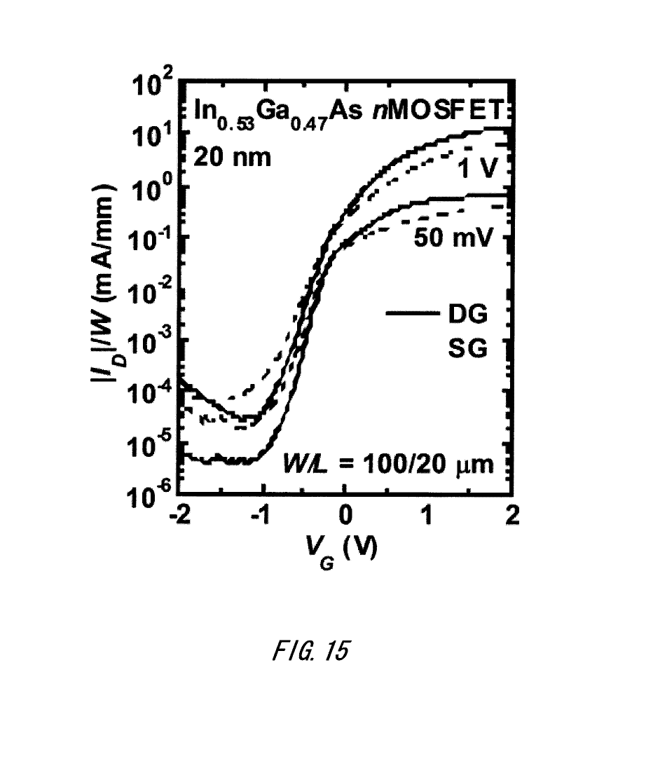

FIG. 14 and FIG. 15 show a characteristic relation between the gate voltage and the drain current. The drain current is shown by an absolute value normalized by the gate width. FIG. 14 shows the characteristic of the pMOSFET provided on the Ge wafer, and FIG. 15 shows the characteristic of the nMOSFET provided on the InGaAs layer. The gate width W and the gate length L of each FET were 100 μm and 20 μm, respectively. The thickness of the InGaAs layer was 20 nm. The drawings show cases in which the drain voltage was 1 V and 50 mV respectively. The nMOSFET in FIG. 15 shows a result for a double gate (DG) in addition to a result for a single gate (SG). It is shown by FIG. 14 and FIG. 15 that each FET for the pMOSFET provided on the Ge wafer and the nMOSFET provided on the InGaAs layer is functioning normally. In particular, the current on-off ratio was about 10⁶, during the double gate operation of the nMOSFET provided on the InGaAs layer, which exhibits a favorable transistor characteristic.

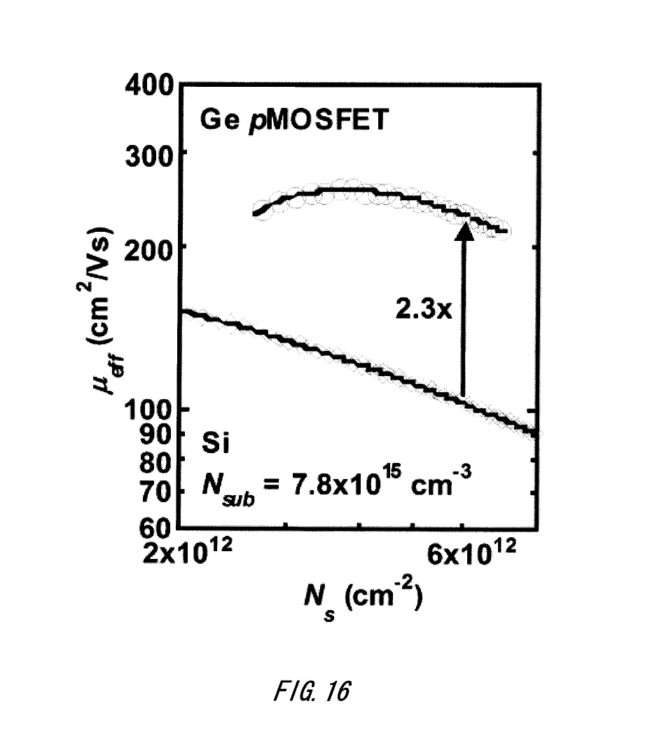

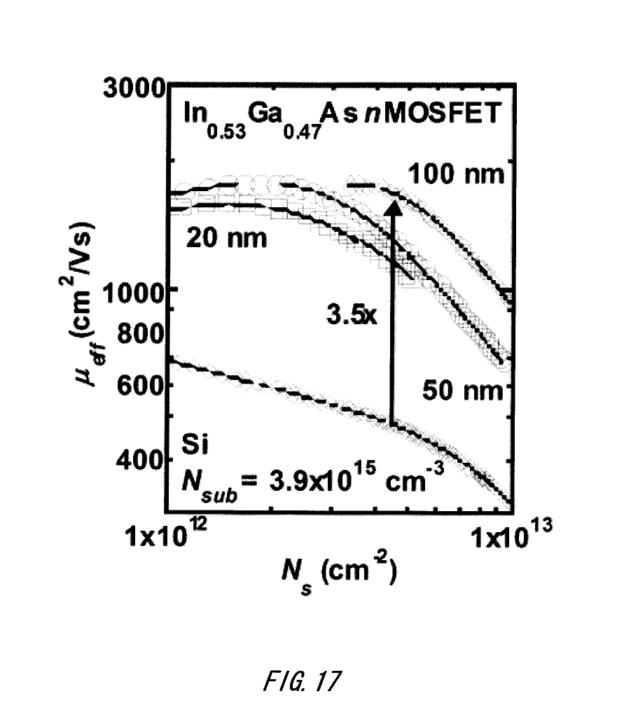

FIG. 16 shows a relation of the hole mobility of the pMOSFET provided on the Ge wafer in relation to the charge density Ns. FIG. 17 shows a relation of the electron mobility of the nMOSFET provided on the InGaAs layer in relation to the charge density Ns. FIG. 17 shows each case in which the thickness of the InGaAs layer was 20 nm, 50 nm, and 100 nm. FIG. 16 and FIG. 17 show the mobility when Si is used as an active layer, as a comparison example. FIG. 16 and FIG. 17 show that each of the hole mobility of the pMOSFET provided on the Ge wafer and the electron mobility of the nMOSFET provided on the InGaAs layer have a high value, specifically 260 cm²/Vs, and 1800 cm²/Vs. These values are respectively 2.3 and 3.5 times as compared to the case of Si.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order. In addition, such a phrase as “a first layer is “above” a second layer” includes both cases in which the first layer is provided to be in contact with the upper plane of the second layer, and there is another layer interposed between the lower plane of the first layer and the upper plane of the second layer. The terms related to directions (e.g., “upper”, “lower”) respectively show relative directions in a semiconductor wafer and a semiconductor device, and should not be interpreted as absolute directions in relation to the outside reference plane such as the ground surface.

What is claimed is:

1. A semiconductor device comprising:
a base wafer made of a Ge crystal;
a semiconductor crystal layer that is positioned above a partial region of the base wafer and made of a Group III-V compound semiconductor;
a P-channel-type MISFET having a channel formed in a part of an area of the base wafer above which the semiconductor crystal layer does not exist and having a first source and a first drain; and
an N-channel-type MISFET having a channel formed in a part of the semiconductor crystal layer and having a second source and a second drain, wherein
the first source and the first drain are made of a compound having a Ge atom and a nickel atom, a compound having a Ge atom and a cobalt atom, or a compound having a Ge atom, a nickel atom, and a cobalt atom, and
the second source and the second drain are made of a compound having a Group III atom, a Group V atom, and a nickel atom, a compound having a Group III atom, a Group V atom, and a cobalt atom, or a compound having a Group III atom, a Group V atom, a nickel atom, and a cobalt atom.

2. The semiconductor device according to claim 1, further comprising:
a separation layer that is positioned between the base wafer and the semiconductor crystal layer, and electrically separates the base wafer from the semiconductor crystal layer.

3. The semiconductor device according to claim 2, wherein
the base wafer is in contact with the separation layer,
an area of the base wafer that is in contact with the separation layer is conductive, and
a voltage applied to the area of the base wafer that is in contact with the separation layer functions as a back gate voltage with respect to the N-channel-type MISFET.

4. The semiconductor device according to claim 1, wherein
the base wafer is in contact with the semiconductor crystal layer on a bonding plane,
impurity atoms exhibiting a p-type or n-type conductivity type are contained in an area of the base wafer in the vicinity of the bonding plane, and
impurity atoms exhibiting a conductivity type different from the conductivity type of impurity atoms contained in the base wafer are contained in an area of the semiconductor crystal layer in the vicinity of the bonding plane.

5. A semiconductor wafer used for the semiconductor device according to claim 1, the semiconductor wafer comprising:
the base wafer and the semiconductor crystal layer, wherein
the semiconductor crystal layer is positioned above a part of a surface of the base wafer.

6. The semiconductor wafer according to claim 5, further comprising:
a separation layer that is positioned between the base wafer and the semiconductor crystal layer, and electrically separates the base wafer from the semiconductor crystal layer.

7. The semiconductor wafer according to claim 6, wherein
the separation layer is made of an amorphous insulator.

8. The semiconductor wafer according to claim 6, wherein
the separation layer is made of a semiconductor crystal having a wider band gap than a band gap of a semiconductor crystal constituting the semiconductor crystal layer.

9. The semiconductor wafer according to claim 5, wherein
the base wafer is in contact with the semiconductor crystal layer on a bonding plane,
impurity atoms exhibiting a p-type or n-type conductivity type are contained in an area of the base wafer in the vicinity of the bonding plane, and
impurity atoms exhibiting a conductivity type different from the conductivity type of impurity atoms contained in the base wafer are contained in an area of the semiconductor crystal layer in the vicinity of the bonding plane.

10. The semiconductor wafer according to claim 5, comprising:
a plurality of the semiconductor crystal layers, wherein
each of the plurality of semiconductor crystal layers is arranged regularly within a plane parallel to an upper plane of the base wafer.

11. A method for producing the semiconductor wafer according to claim 5, the method comprising:
epitaxial growth of forming the semiconductor crystal layer on a semiconductor crystal layer forming wafer by epitaxial growth; and
bonding the semiconductor crystal layer to a partial region of the base wafer or to a region thereabove.

12. A method for producing the semiconductor wafer according to claim 5, comprising:
forming, above a partial region of the base wafer, a separation layer made of a semiconductor crystal having a wider band gap than a band gap of a semiconductor crystal constituting the semiconductor crystal layer by epitaxial growth; and
forming the semiconductor crystal layer on the separation layer by epitaxial growth.

13. A method for producing the semiconductor wafer according to claim 5, comprising:
incorporating impurity atoms exhibiting a p-type or n-type conductivity type into the vicinity of a surface of the base wafer; and
forming the semiconductor crystal layer above a part of the surface of the base wafer by epitaxial growth, wherein
in the forming of the semiconductor crystal layer by epitaxial growth, the base wafer is doped with impurity atoms exhibiting a conductivity type different from a conductivity type of impurity atoms contained in the base wafer.

14. A method according to claim 11, for producing the semiconductor wafer, the method comprising, prior to forming a semiconductor crystal layer on the semiconductor crystal layer forming wafer, forming a crystalline sacrificial layer on a surface of the semiconductor crystal layer forming wafer by epitaxial growth; wherein
the semiconductor crystal layer forming wafer is separated from the semiconductor crystal layer having been formed by epitaxial growth on the semiconductor crystal layer forming wafer, by removing the crystalline sacrificial layer, after bonding the semiconductor crystal layer to the base wafer.

15. The method according to claim 11, for producing the semiconductor wafer, the method comprising:
any one of patterning the semiconductor crystal layers in a regular arrangement after having formed the semiconductor crystal layers by epitaxial growth, or forming the semiconductor crystal layers in a regular arrangement by selective epitaxial growth.

16. A method for producing a semiconductor device, the method comprising:
producing a semiconductor wafer comprising the semiconductor crystal layer by using the method according to claim 11 for producing the semiconductor wafer;
forming a gate electrode via a gate insulating layer, on an area of the base wafer above which the semiconductor crystal layer does not exist, and on the semiconductor crystal layer;
forming a metal film selected from the group consisting of a nickel film, a cobalt film, and a nickel/cobalt alloy film, on a source electrode forming region of the base wafer, on a drain electrode forming region of the base wafer, on a source electrode forming region of the semiconductor crystal layer, and on a drain electrode forming region of the semiconductor crystal layer;
heating the metal film, thereby forming, in the base wafer, a first source and a first drain made of a compound having a Ge atom and a nickel atom, a compound having a Ge atom and a cobalt atom, or a compound having a Ge atom, a nickel atom, and a cobalt atom, and forming, in the semiconductor crystal layer, a second source and a second drain made of a compound having a Group III atom, a Group V atom, and a nickel atom, a compound having a Group III atom, a Group V atom, and a cobalt atom, or a compound having a Group III atom, a Group V atom, a nickel atom, and a cobalt atom; and
removing a non-reacted portion of the metal film.
